(19) United States
(12) Patent Application Publication
(10) Pub. No.: US 2012/0052689 A1
(43) Pub. Date: Mar. 1, 2012

(54) PLASMA ETCHING METHOD AND APPARATUS THEREOF

(75) Inventor: Ken Tokashiki, Seongnam-si (KR)

(73) Assignee: SAMSUNG ELECTRONICS CO., LTD., Suwon-si (KR)

(21) Appl. No.: 12/969,660

(22) Filed: Dec. 16, 2010

(30) Foreign Application Priority Data
Sep. 1, 2010 (KR) 10-2010-0085645

(51) Int. Cl. H01L 21/302; C23F 1/08

(52) U.S. Cl. 438/714; 156/345.28

(57) ABSTRACT

A method of etching a substrate includes positioning the substrate on a substrate support within a chamber, etching a formation in the substrate in the presence of plasma within the chamber, decreasing a positive charge within the formation, and further etching the formation in the substrate in the presence of plasma after decreasing the positive charge within the formation.

### CROSS-REFERENCE TO RELATED APPLICATION

A claim of priority under 35 U.S.C. §119 of Korean Patent Application No. 10-2010-0085645, filed Sep. 1, 2010, the disclosure of which is incorporated herein by reference in its entirety.

### BACKGROUND

The inventive concepts described herein generally relate to device fabrication systems, such as semiconductor device fabrication, and more particularly, the inventive concepts relate to plasma etching techniques and apparatuses.

In the case of semiconductor device fabrication, plasma etching is utilized to form a variety of different circuit patterns. As examples, plasma etching may be used to form a hole or trench in a semiconductor substrate, to pattern contacts and metallic lines, and so on. The plasma etching may be carried out directly on the underlying semiconductor bulk of the semiconductor substrate, and on one or more semiconductor and/or conductive and/or dielectric layers of the semiconductor substrate.

Generally, plasma etching involves a process in which a plasma of ionized reactive gas is formed in a chamber containing a specimen to be etched. Chemisorption occurs between reactive particles of the plasma and exposed surface material of the specimen. The resultant reaction product molecules undergo desorption and are removed from the chamber. In this manner, exposed surface material of the specimen is chemically removed (i.e., etched). In addition, there may be some physical removal of specimen material resulting from physical collisions between the plasma ions and the expose surfaces of the specimen.

There are a variety of different types of plasma etching device configurations, but each generally relies on the use of a high frequency power (e.g., a Radio Frequency (RF) power) to ion a reaction gas within the process chamber. Common examples of plasma etching devices include Capacitively Coupled Plasma (CCP) devices and Inductively Coupled Plasma (ICP) device. In the case of ICP, plasma is generated by inductive coupling of the high frequency power utilizing an antenna located adjacent the chamber. In contrast, in the case of CCP, plasma generated by applying the high frequency power to capacitively coupled cathode and an anode electrodes located within the chamber.

### SUMMARY

According to an aspect of the inventive concepts, a method of etching is provided which includes positioning a substrate on a substrate support within a chamber, etching a formation in the substrate in the presence of plasma within the chamber, decreasing a positive charge within the formation, and further etching the formation in the substrate in the presence of plasma after decreasing the positive charge within the formation.

According to another aspect of the inventive concepts, a method of etching a substrate is provided which includes applying pulsed first and second frequency power signals to an etch chamber to cyclically etch a formation in the substrate within the etch chamber, where a frequency of the first frequency power signal is less than a frequency of the second frequency power signal. The method further includes applying a pulsed DC voltage to an electrode within the chamber, and synchronizing the pulsed first and second frequency power signals and the pulsed DC voltage to periodically reduce a positive charge within the formation during the cyclical etching of the formation.

According to another aspect of the inventive concepts, a method of etching a substrate is provided which includes positioning the substrate on a substrate support including a first electrode in a chamber, and etching a formation in the substrate by applying a pulsed first frequency power signal to the first electrode, and by applying a negative DC voltage and a pulsed second frequency power signal to a second electrode which is spaced from the first electrode. The first frequency is less than the second frequency, and a pulse-off period of the first frequency power signal at least partially overlaps a pulsed-off period of the second frequency power signal. The method further includes decreasing a positive charge within the chamber by increasing the magnitude of the negative DC voltage during at least a portion of an overlapping pulse-off period of the first and second frequency power signals, and further etching the formation in the substrate by decreasing the magnitude of the negative DC voltage.

According to still another aspect of the inventive concepts, an etching apparatus is provide which includes a chamber, a substrate support in the chamber and including a first electrode, a second electrode in the chamber and spaced from the first electrode, a high frequency supply unit, a DC supply unit and a control unit. The high frequency supply unit is for supplying a pulsed first frequency power signal to the first electrode and a pulsed second frequency power signal to one of the first and second electrodes, where a frequency of the first frequency power signal is less than a frequency of the second frequency power signal. The DC supply unit is for supplying a pulsed DC voltage to one of the first and second electrodes. The a control unit for synchronizing the pulsed DC voltage and the pulsed first and second frequency power signals such that a magnitude of pulsed DC voltage during at least a portion of each pulse-off period of the first and second frequency power signals.

According to yet another aspect of the inventive concepts, an etching apparatus is provided which includes a chamber, a substrate support in the chamber and including a first electrode, an inductive coil adjacent the chamber, a high frequency supply unit, a DC supply unit, and a control unit. The high frequency supply unit is for supplying a pulsed first frequency power signal to the first electrode and a pulsed second frequency power signal to the inductive coil, wherein a frequency of the first frequency power signal is less than a frequency of the second frequency power signal. The DC supply unit is for supplying a pulsed DC voltage to one of the first and second electrodes. The control unit is for synchronizing the pulsed DC voltage and the pulsed first and second frequency power signals such that a magnitude of pulsed DC voltage is increased during at least a portion of each pulse-off period of the first and second frequency power signals.

### BRIEF DESCRIPTION OF THE DRAWINGS

The accompanying drawings are included to provide a further understanding of the inventive concepts, and are incorporated in and constitute a part of this specification. The drawings illustrate exemplary embodiments of the inventive concepts and, together with the description, serve to explain principles of the inventive concepts. In the drawings:

FIG. 1 illustrates a plasma etching device according to an embodiment of the inventive concepts;

FIG. 2 is a waveform diagram for use in describing a plasma etching method according to an embodiment of the inventive concepts;

FIG. 3 illustrates variations of physical parameters generated by a plasma etching according to an embodiment of the inventive concepts;

FIG. 4 is a diagram for use in describing a secondary electron flux and plasma potential generated by a plasma etching according to an embodiment of the inventive concepts;

FIG. 5 illustrates a cross-sectional etching model for use in describing a plasma etching according to an embodiment of the inventive concepts;

FIG. 6 is a waveform diagram for use describing another embodiment of a plasma etching method according to the inventive concepts;

FIG. 7 is a waveform diagram for use describing another embodiment of the plasma etching method according to the inventive concept;

FIG. 8 illustrates another embodiment of a plasma etching device according to the inventive concepts;

FIG. 9 illustrates still another embodiment of a plasma etching device according to the inventive concepts;

FIG. 10 illustrates yet another embodiment of a plasma etching device according to the inventive concepts; and

FIG. 11 is a flowchart for use in describing a plasma etching method according to one or more embodiments of the inventive concepts.

### DETAILED DESCRIPTION OF THE EMBODIMENT

Various embodiments and examples of embodiments of the inventive concept will be described more fully hereinafter with reference to the accompanying drawings. In the drawings, the sizes and relative sizes and shapes of elements, layers and regions, such as implanted regions, shown in section may be exaggerated for clarity. In particular, the cross-sectional illustrations of the semiconductor devices and intermediate structures fabricated during the course of their manufacture are schematic. Also, when like numerals appear in the drawings, such numerals are used to designate like elements.

Furthermore, spatially relative terms, such as “upper,” and “lower” are used to describe an element's and/or feature's relationship to another element(s) and/or feature(s) as illustrated in the figures. Thus, the spatially relative terms may apply to orientations in use which differ from the orientation depicted in the figures. Obviously, though, all such spatially relative terms refer to the orientation shown in the drawings for ease of description and are not necessarily limiting as embodiments according to the inventive concept can assume orientations different than those illustrated in the drawings when in use.

It will also be understood that when an element or layer is referred to as being “on” or “connected to” another element or layer, it can be directly on or directly connected to the other element or layer or intervening elements or layers may be present. In contrast, when an element or layer is referred to as being “directly on” or “directly connected to” another element or layer, there are no intervening elements or layers present.

Furthermore, as used herein, the term “and/or” includes any and all practical combinations of one or more of the associated listed items.

It will be understood that although the terms first, second, third etc. are used herein to describe various elements, regions, layers, etc., these elements, regions, and/or layers are not limited by these terms. These terms are only used to distinguish one element, layer or region from another.

Other terminology used herein for the purpose of describing particular examples or embodiments of the inventive concept is to be taken in context. For example, the terms “comprises”, “comprising”, “includes”, and “including” when used herein specifies the presence of stated features or processes but does not preclude the presence or additional features or processes.

Hereinafter, exemplary embodiments of the inventive concepts will be described in detail with reference to the accompanying drawings.

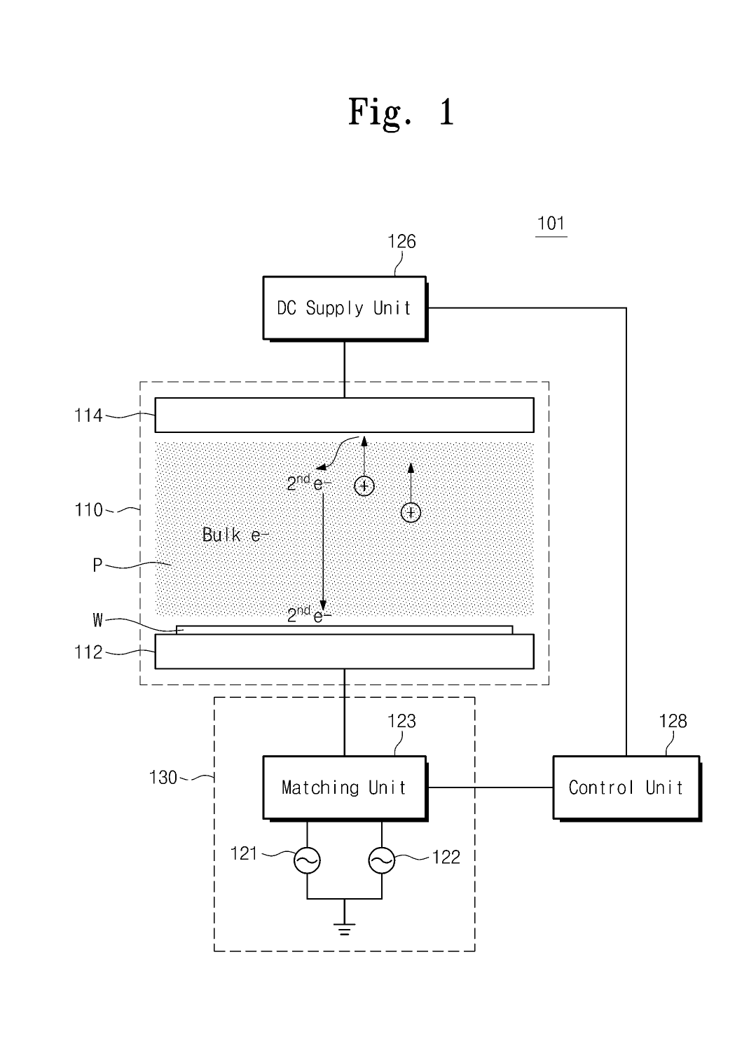

FIG. 1 illustrates a plasma etching device according to an embodiment of the inventive concepts. Referring to FIG. 1, the plasma etching device 101 of this example includes a chamber 110, a first electrode 112, a second electrode 114, a first high frequency source 121, a second high frequency supply course 122, a matching unit 123, DC supply unit 126 and a control unit 128.

The chamber 110 is configured to contain plasma P within a process space of the chamber 110.

The first electrode 112 generally constitutes all or part of a substrate support for supporting a substrate, e.g., a wafer W, within the chamber 110. The configuration of the substrate support is not limited. For example, the substrate support may include a platform or chuck (not shown) interposed between the first electrode 112 and the wafer W. In this case, the platform or chuck may rest directly on the first electrode 112, or be spaced from the first electrode 112.

As shown in FIG. 1, the first and second electrodes 112 and 114 confront each other across the process space of the chamber 110. As examples, the first electrode 112 and the second electrode 114 may be made of a silicon-containing conductive material such as a conductive silicon (Si) or silicon carbide (SiC). However, the inventive concepts are not limited to these specific examples.

In the example of this embodiment, the substrate to be etched is a semiconductor wafer W, which optionally may include one or more conductive and/or semiconductive and/or insulating layers deposited therein. However, the inventive concepts are not limited to the substrate being a semiconductor wafer. As such, the term “substrate” is broadly defined herein as any item containing one or more materials and/or layers capable of being etched using the plasma etching techniques and devices described herein.

In the example of this embodiment, the first high frequency source 121, the second high frequency source 122, and the matching unit 123 constitute a high frequency supply unit 130 which supplies pulsed high frequency power to the bottom electrode 112. This will be described in more detail below.

The first high frequency source 121 generates a first high frequency power signal of a first frequency, and the second high frequency source 122 generates a second high frequency power signal of a second frequency. In the example of this embodiment, the first frequency is less than the second frequency. For example, each of the first and second frequencies may be in the RF range. As another example, the first frequency may be an RF frequency of 15 MHz or less, and the second frequency may in the RF range or higher.

As is understood in the art, the second (higher frequency) high frequency signal is utilized to generate plasma P within the process space of the chamber 110, while the first (lower frequency) high frequency signal is utilized to excite plasma ions within the process space such that they become incident on the wafer W. As discussed in the background section herein, exposed surface material of wafer W is chemically and/or physically removed (i.e., etched). Further, although not shown in FIG. 1, the plasma etching device 101 may include other components, such as one or more gas inlets for introduction of one or more process gas(es) into the chamber 110, and one or more gas outlets for exhaustion of reaction gas(es) and etch byproducts from the chamber 110. The plasma etch device 101 may also include, for example, an annular-shaped element of Si and/or quartz material surrounding the wafer W.

As shown in FIG. 1, the first and second high frequency power signals from the respective sources 121 and 122 are applied to the matching unit 123. As will be described in more detail later, in the example of this embodiment, the matching unit 123 is an electronic circuit that is responsive to the control unit 128 to pulse modulate the first and second high frequency power signals from the respective sources 121 and 122, and to apply the pulse modulated high frequency power signals to the lower electrode 112. In addition, the matching unit 123 may also match a load impedance of the sources 121 and 122 to an impedance of the lower electrode 112 in order to transfer maximum power to the lower electrode 112. It will be understood that the matching unit 123 may be integrated into a single circuit block, or functionally separated into two or more circuit blocks.

Still referring to FIG. 1, in the example of the present embodiment, the DC (direct current) supply unit 126 is responsive to the control unit 128 to supply a pulsed negative DC voltage to the second electrode 114. In the example of the present embodiment, the pulsed negative DC voltage transitions (pulses) between a LOW negative voltage and a HIGH negative voltage.

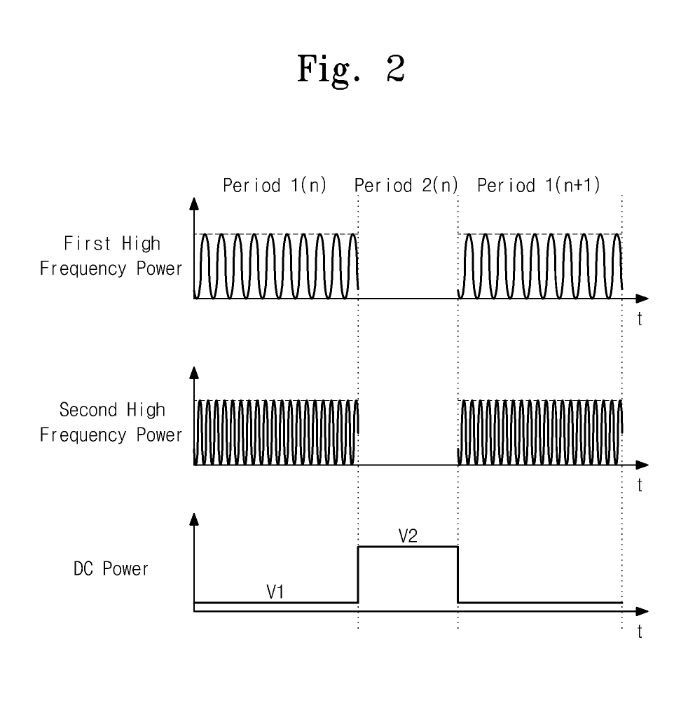

The control unit 128, in the example of this embodiment, controls a pulse timing action of the matching unit 123 and the DC supply unit 126. In particular, as will be described by way example below, the control unit 128 synchronizes the pulse modulation of the first and second high frequency power signals applied to the first electrode 112 with the pulsed negative DC voltage applied to the second electrode 114. In one specific example described later in connection with FIG. 2, the control unit 128 may be an electronic circuit that applies a ON/OFF (1-bit) control signal to the matching unit 123, and a LOW/HIGH (1-bit) control signal to the DC supply unit 126. Examples of a pulse frequency and duty ratio of the control signals generated by control unit 128 are presented later herein.

It is noted that the matching unit 123 and/or the control unit 128 and/or the DC supply unit 126 may be combined into a single circuit block, or functionally separated into separate circuit blocks. The embodiments are not limited by any particular internal circuit and/or software configuration of these units.

Attention is now directed to FIG. 2 which is presented to explain one example of the operation of the plasma etching device of FIG. 1 according to an embodiment of the inventive concepts.

Referring collectively to FIGS. 1 and 2, Periods 1(n) and 2(n) together constitute an n^{th} cycle (n is an integer) of a cyclical etch process according to an embodiment of the inventive concepts. In particular, FIG. 2 illustrates the n^{th} cycle of the pulsed first and second high frequency power signals and the pulsed negative DC supply voltage, as well as a Period 1(n+1) of a next (n+1)^{th} cycle of the cyclical etch process. As mentioned above, in the example of this embodiment, these signals are synchronized by the control unit 128. In particular, in the example of this embodiment, the control unit 128 is configured to control the matching unit 123 and the DC supply unit 126 such that the pulsed first and second high frequency power signals are ON (Period 1(n)) when the DC negative supply voltage is a LOW negative voltage V1, and the first and second high frequency power signals are OFF (Period 2(n)) when the DC negative supply voltage is a HIGH negative voltage V2.

The pulse frequency of the signals illustrated in FIG. 2 may, for example, be in a range of about 100 Hz to 100 kHz, and the duty ratio may be in a range of about 10% to 99%. As a specific example, the pulse frequency of the signals illustrated in FIG. 2 may be about 10 kHz and the duty ratio may be about 70%. Here, the duty ratio is the ratio of Period 1(n) to the sum of Periods 1(n) and 2(n). However, the inventive concepts are not limited to these specific ranges and examples.

Still referring to FIG. 2, it can be seen that the pulses of the first and second high frequency power signals are synchronized, i.e, the first and second high frequency power signals are turned ON and OFF simultaneously. As specific examples, during the ON periods (Periods 1(n) and 1(n+1) in FIG. 2), the first high frequency power signal and the second high frequency power signal may be about 2000 W and about 8000 W respectively. Again, however, the inventive concepts are not limited to these specific examples.

In synchronization with the ON/OFF periods of the high frequency power signals, the negative DC voltage is transitioned between the LOW negative voltage V1 and the HIGH negative voltage V2. In particular, as shown in FIG. 2, the negative DC supply voltage is transitioned from a first negative voltage V1 to a second negative voltage V2 when the high frequency power signals are OFF, and is transitioned from the second negative voltage V2 to the first negative voltage V1 the high frequency power signals are ON. For example, a magnitude of the first negative voltage V1 may range from about 0V to about 500V, and a magnitude of the second negative voltage V2 may range from about 200V to about 2000V. As a more specific example, a magnitude of the first negative voltage V1 may range from about 200V to about 300V, and a magnitude of the second negative voltage may range from about 400V to about 2000V. Once again, however, the inventive concepts are not limited to these specific examples.

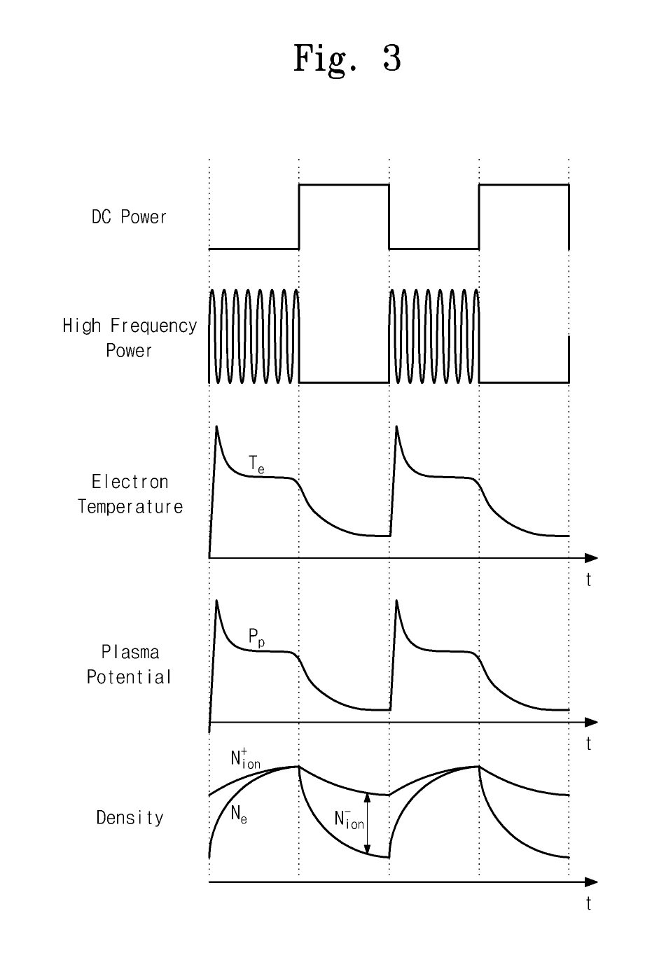

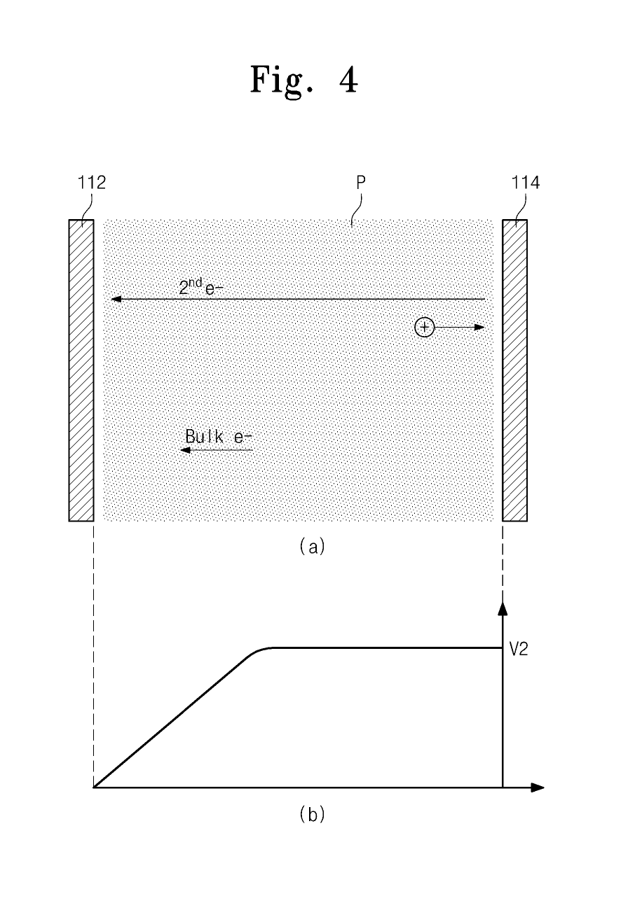

Attention is now directed to FIG. 3 for a description of variations in physical parameters in a plasma etching technique as shown in FIG. 2, and to FIG. 4 for a description of physical phenomena occurring during an OFF period of the high frequency power signals as shown in FIG. 2. Section (a) of FIG. 4 is for describing the flux of secondary electrons, and section (b) of FIG. 4 illustrates a potential within the plasma.

Referring collectively to FIGS. 2 to 4, when the first and second high frequency power signals are turned-off (Period 2(n) begins), a positive ion density (N⁺ᵢₒₙ), an electron density (Nₑ) an electron temperature (Tₑ) and a plasma potential (Pₚ) are reduced. In addition, a negative ion density (N⁻ᵢₒₙ), corresponding to a difference between N^{+hd ion} and Nₑ, is increased.

In addition, as described above, the negative DC voltage is increased from the first negative voltage V1 to the second negative voltage V2 during the Period 2(n). As a result, referring to FIG. 4, positive ions (circle-+) remaining within the plasma P are accelerated towards and collide with the second electrode 114 so to generate secondary electrons (2^{nd} e⁻). The thus generated secondary electrons (2^{nd} e⁻), which have an energy in accordance with the second voltage V2, pass through the plasma P and are incident towards the first electrode 112 (i.e., the wafer W). In addition, any electrons (bulk e⁻) remaining within the plasma P may also be incident towards the first electrode 112. However, the secondary electrons (2^{nd} e⁻) may constitute the majority of electrons incident towards the first electrode 112.

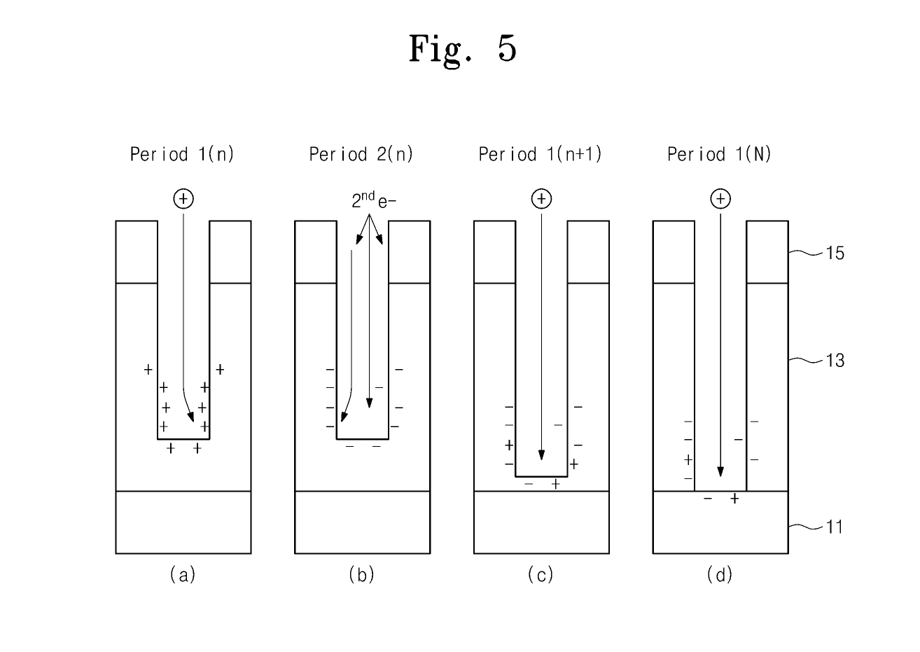

Attention is now directed to the cross-sectional views of FIG. 5 for use in describing an etch mechanism in a plasma etching device and technique described above. In FIG. 5, reference number 11 denotes a substrate, reference number 13 denotes a layer to be etched (etched layer), and reference number 15 denotes an etch mask. The etched layer 13 may, for example, be an insulating layer, and the substrate 11 may, for example, be a semiconductor substrate (or wafer) or a transparent substrate. However, the inventive concepts are not limited to these specific examples. Also, the etched layer 13 may be formed of multiple material layers, and may be a contiguous part of the substrate 11.

Referring to cross-sectional view (a) of FIG. 5, during Period 1(n) in which the first and second high frequency power signals are ON and the negative DC voltage is V1 (low), positive ions (circle-+) within the plasma are directed towards the substrate 11 (first electrode 112) so as to etch a formation (e.g., hole or trench) in the etched layer 13 exposed through the mask 15. As a result of an electron shading effect, the quantity of electrons incident into the formation may be smaller than that of the positive ions (circle-+). Accordingly, the positive ions (circle-+) may accumulate at a bottom region of the formation.

The accumulation of positive ions (circle-+) at a bottom region of the formation can adversely impact the etching efficacy as the formation becomes deeper. This is because the accumulated positive ions at the bottom region of the formation reduce the quantity of incident positive ions from the plasma at the bottom region of the formation during etching. As a result, an etch rate is reduced with an increase in etch depth, thereby limiting an aspect ratio of the formation. For example, a maximum achievable aspect ratio may be on the order of 20:1.

As will be described next, the embodiment of the inventive concepts is at least partially directed to enhancing an etch efficacy by reducing the accumulation of positive ions at the bottom region of the formation.

Reference is made to the cross-sectional view (b) of FIG. 5, which represents the Period 2(n) in which the first and second high frequency power signals are OFF, and the negative DC voltage is V2 (high). At this time, as described previously in connection with FIG. 4, the positive ions (circle-+) remaining within the plasma P accelerate and collide with the second electrode 114, and secondary electrons (2^{nd} e⁻) are generated and incident towards the first electrode 112. The resultant flow of the secondary electrons (2^{nd} e⁻) enters deep within the formation to thereby neutralize the positive charge of the previously accumulated positive ions at the bottom region of the formation. In addition, sufficient quantities of secondary electrons (2^{nd} e⁻) may accumulate to result in a net-negative charge in the bottom of the formation as depicted in cross-sectional view (b) of FIG. 5. This has the effect of enhancing the etch efficacy in a next cycle of the etching process as described next.

Attention is now directed to cross-sectional view (c) of FIG. 5, which corresponds to Period 1(n+1) of FIG. 2. Here, the first and second high frequency power signals are ON, and the negative DC supply voltage is V1 (low). As such, an etching action occurs as described previously. Since the positive ions at the bottom region were neutralized in Period 2(n), the positive ions produced to the etch Period 1(n+1) are not impeded (repelled) within the bottom region of the formation, and thus the etching efficacy is enhanced. Further, since bottom region of the formation may have a net negative charge at the conclusion of Period 2(n) as described above, the positive ions produced in the etch Period 1(n+1) may be accelerated with greater energy into the bottom region of the formation, thus further enhancing the etching efficacy.

In an embodiment of the inventive concepts, the etching process is cyclically repeated such that each etch cycle includes Periods 1(1:N) and 2(1:N), where N is the total number of cycles. Cross-sectional view (d) of FIG. 5 is representative of the finally etched formation after Period 1(N) of the N^{th} (last) cycle. It will be apparent that the neutralization of charges of Period 2(N) of the last cycle may optionally be omitted.

By decreasing a positive charge within the bottom region of the formation during each of the Periods 2(1:N), the etch efficacy during each of the etch Periods (2:N) is enhanced, thereby allowing for an etched formation of a greater aspect ratio. For example, an aspect ratio on the order of 50:1 or higher may be achieved.

As mentioned above, examples of the etch formation include a hole or trench. However, the formation itself is not limited, and other examples include the formation of nano-scale circuit patterns including vias, holes, grooves, contacts, line patterns, and so on.

In the embodiment described above in connection with FIGS. 1 through 5, the control unit 128 is configured to control a pulse timing of the DC supply unit 126 and the matching unit 123 such that the OFF period of the first and second high frequency power signals is synchronized with the HIGH negative voltage V2 period of the pulsed negative DC supply voltage. However, the inventive concepts are not limited thereto, and variations within the scope of the inventive concepts will become apparent to those skilled in the art. As one example, the high frequency sources 121 and 122 and/or the matching unit 123 may be configured to generate pulsed first and second high frequency signals independently of the control unit 128. In this case, the control unit 128 may be configured to detect (or receive a signal indicative of) the pulse frequency and duty ratio of the first and second high frequency signals, and to then control the DC supply unit 126 such that the OFF period of the first and second high frequency signals is synchronized with the HIGH negative voltage V2 period of the pulsed negative DC supply voltage. Conversely, as another example, DC supply unit 126 may be configured to generate a pulsed negative DC supply voltage independently of the control unit 128. In this case, the control unit 128 may be configured to detect (or receive a signal indicative of) the pulse frequency and duty ratio of the pulsed DC negative supply voltage, and to then control the high frequency sources 121 and 122 and/or the matching unit 123 such that the OFF period of the first and second high frequency signals is synchronized with the HIGH negative voltage V2 period of the pulsed negative DC supply voltage.

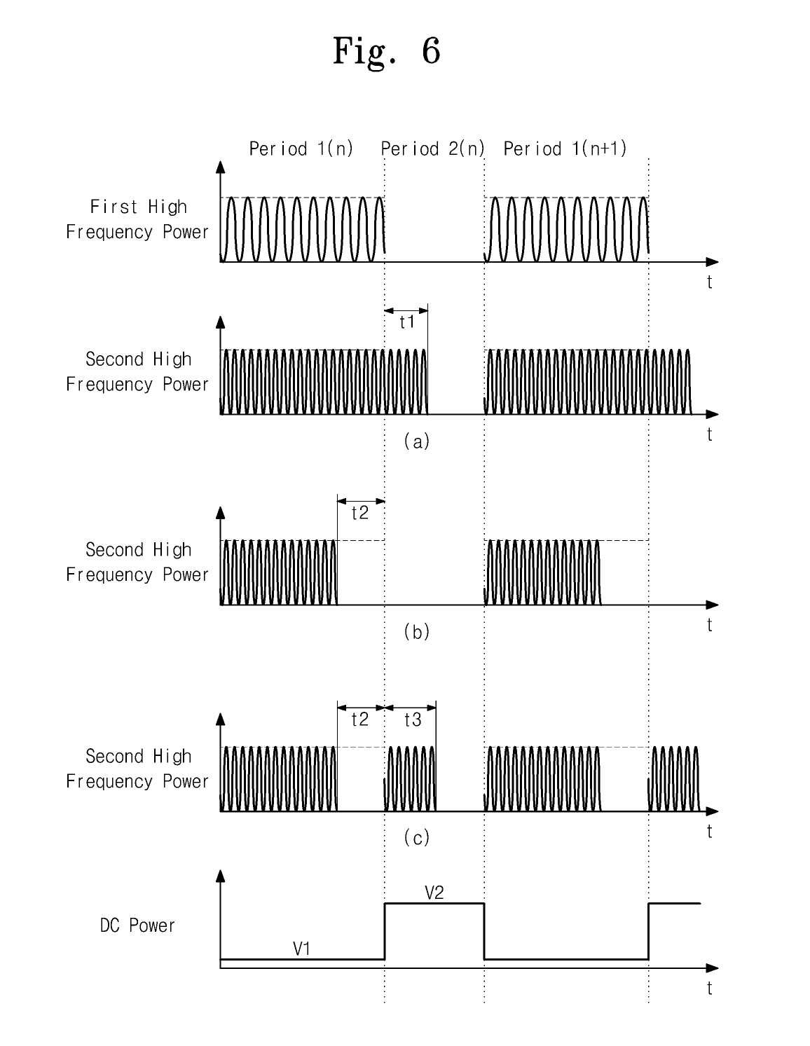

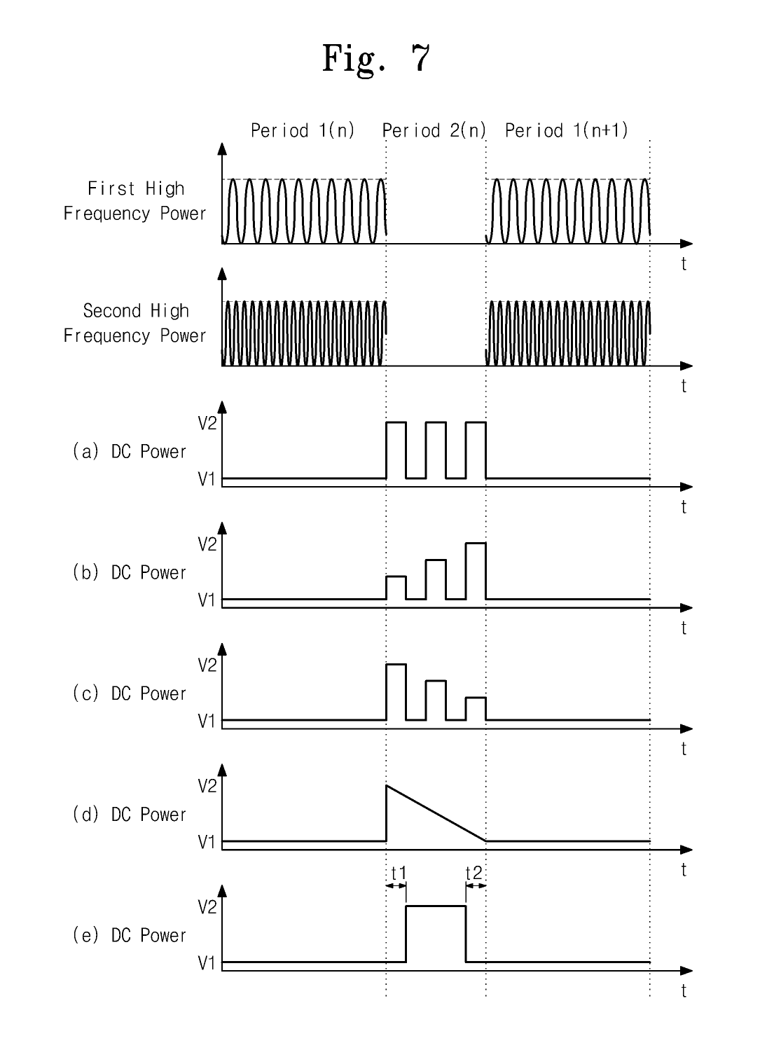

Moreover, as described next in connection with FIGS. 6 and 7, the inventive concepts are not limited to the specific pulse patterns shown in FIG. 2.

Plasma etching techniques according to other embodiments of the inventive concepts will now be described with reference to FIG. 6. In particular, FIG. 6 depicts three separate embodiments labeled (a) through (c).

Referring to (a) of FIG. 6, this embodiment is characterized by the ON period of the second high frequency power signals extending by time t1 into the Period 2(n) (in which the first high frequency power signal is OFF and the negative DC voltage is V2 (high)). This embodiment may have the advantage of maintaining an electron density within the plasma during an initial portion of the Period 2(n), thereby increasing the amount of bulk electrons (bulk e− of FIG. 4) within the process space during the Period 2(n). This can increase the total quantity of electrons incident towards the first electrode 112 that are available to neutralize positive charges within the formation during the Period 2(n).

However, the inventive concepts also encompass turning OFF the second high frequency power signal before the end of the each period of each cycle of the etching process. This is shown by way of example in (b) of FIG. 6, where the second high frequency power signal is turned OFF a time t2 before the end of Period 1(n). Since sufficient plasma may remain to achieve etching for a period of time after the second high frequency power signal is turned OFF, this variation of the inventive concepts may be effective in reducing power consumption.

Another variation of the inventive concepts is shown at (c) of FIG. 6. Here, in each cycle, the second high frequency power signal is turn OFF at time t2 before the end of Period 1(n) of the process cycle, and then turned back ON for a time period t3 during Period 2(n) of the process cycle. The variation may achieve the same benefits as discussed above in connection with variations (a) and (b) of FIG. 6.

It should be noted that the inventive concepts are not limited to the specific examples of FIGS. 2 and 6, and other variations in the pulse parameters of the first and second high frequency power signals will be apparent to those skilled in the art while still falling within the scope and spirit of the inventive concepts. In addition, as explained next, the pulse parameters of the negative DC voltage applied to the electrode 114 are subject to numerous variations.

In particular, FIG. 7 illustrates a non-limiting number of different examples (a)˜(e) of pulse parameters of the negative DC voltage applied to the electrode 114 during the Period 2(n) of an etch process cycle.

The application of a continuous negative DC voltage V2 (high) during each Period 2(n) may result in stress applied the matching unit 123, which can potentially result in long-term damage to the matching unit 123. FIG. 7 illustrates a number of examples (a)˜(e) for reducing the stress applied to the matching unit 123.

Examples (a)˜(c) are each directed to application of multiple high negative DC voltage pulses within the Period 2(n) of each cycle. In other words, each high negative DC voltage pulse is a multi-pulse voltage pulse. In example (a), each of the multiple negative voltage pulses has a same voltage magnitude V2. In example (b), the voltage pulses increase step-wise to a maximum negative voltage V2. In example (c), the voltage pulses decrease step-wise from the negative voltage V2 to a voltage of a lower magnitude. Among these examples, the pulse configuration of example (c) may be particularly suitable in consideration of the reduction in electron density after the first and second high frequency power signals have been turned OFF.

Referring next to example (d) of FIG. 7, here the negative DC voltage is gradually decreased from V2 during the Period 2(n). In other words, the high negative DC voltage pulse is a sloped voltage pulse. In another alternative, the negative DC voltage may be gradually increased to V2 during the Period 2(n).

Example (e) of FIG. 7 illustrates another example in which the pulse width of the negative DC voltage V2 is less then the pulse width of the Period 2(n). In particular, the negative DC voltage applied to the second electrode 114 is increased to V2 at a time period t1 after the start of the Period 2(n), and decreased back to V1 at a time period t2 before the end of the Period 2(n).

The inventive concepts of the various above-described embodiments are at least partially characterized by periodically neutralizing positive charges within an etched formation during plasma etching. In the embodiments above, this is achieved by repetitively executing a cyclical process in which each cycle includes an etch period (Period 1(n)) and a charge neutralizing period (Period 2(n)). Also in the embodiments above, each cycle has the same parameters as a previous cycle of the cyclical process. However, the inventive concepts are not limited in this fashion, i.e., in an alternative embodiment the parameters of one or more cycles may be varied relative to other cycles of the cyclical process.

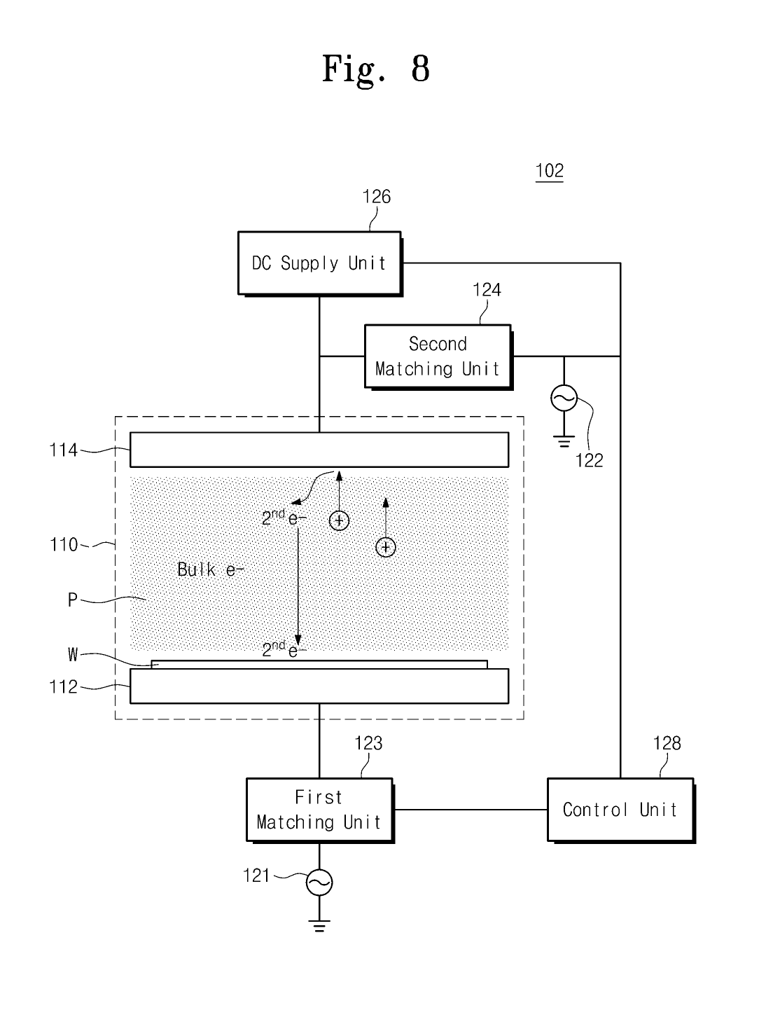

FIG. 8 illustrates a plasma etching device according to another embodiment of the inventive concepts.

Referring to FIG. 8, the plasma etching device 102 of this example includes a chamber 110, a first electrode 112, a second electrode 114, a first high frequency source 121, a second high frequency supply course 122, a first matching unit 123, a second matching unit 124, a DC supply unit 126 and a control unit 128. Here, the first high frequency source 121, the second high frequency supply source 122, the first matching unit 123, and the second matching unit 124 constitute a high frequency supply unit.

The embodiment of FIG. 8 is similar to that of FIG. 1, except that the second high frequency power signal (for plasma generation) from the second high frequency source is applied to the top electrode 114 through a second matching unit 124. Otherwise, an operation of the embodiment of FIG. 8 is the same as that described previously in connection with FIGS. 2-7, and accordingly, a detailed operational description of the embodiment of FIG. 8 is omitted here to avoid redundancy.

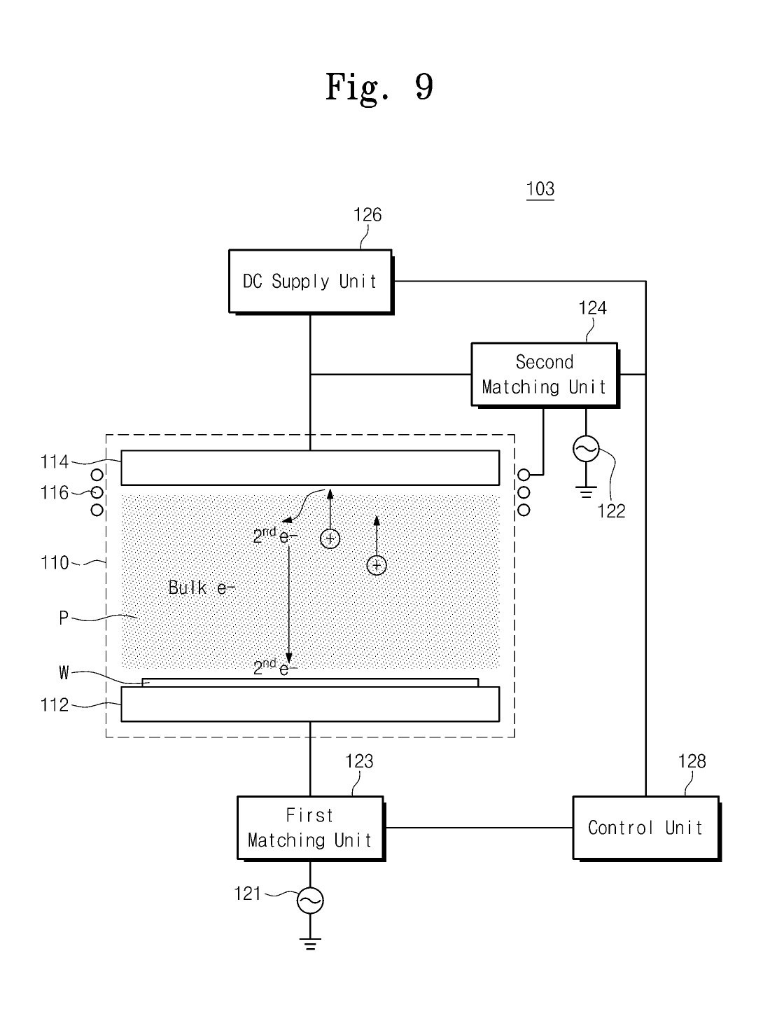

FIG. 9 illustrates a plasma etching device according to still another embodiment of the inventive concepts.

Referring to FIG. 9, the plasma etching device 103 of this example includes a chamber 110, a first electrode 112, a second electrode 114, a first high frequency source 121, a second high frequency supply course 122, a first matching unit 123, a second matching unit 124, an inductive winding 116, a DC supply unit 126 and a control unit 128. Here, the first high frequency source 121, the second high frequency supply source 122, the first matching unit 123, and the second matching unit 124 constitute a high frequency supply unit.

The embodiment of FIG. 9 is similar to that of FIG. 8, except that the second high frequency power signal (for plasma generation) from the second high frequency source is applied to the inductive winding 116 through the second matching unit 124. In other words, the inductive winding 116 is operative to generate plasma P within the process space of the chamber. Otherwise, an operation of the embodiment of FIG. 9 is the same as that described previously in connection with FIGS. 2-7, and accordingly, a detailed operational description of the embodiment of FIG. 9 is omitted here to avoid redundancy.

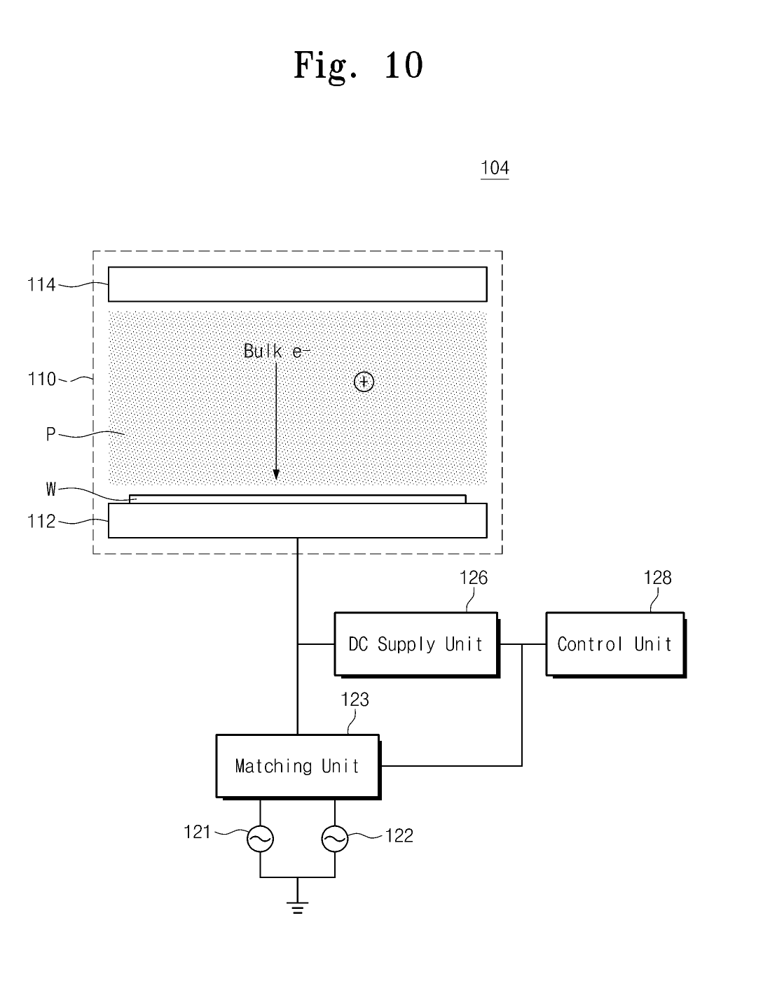

FIG. 10 illustrates a plasma etching device according to yet another embodiment of the inventive concepts.

Referring to FIG. 10, the plasma etching device 104 of this example includes a chamber 110, a first electrode 112, a second electrode 114, a first high frequency source 121, a second high frequency supply course 122, a matching unit 123, a DC supply unit 126 and a control unit 128. Here, the first high frequency source 121, the second high frequency supply source 122, and the matching unit 126 constitute a high frequency supply unit.

The embodiment of FIG. 10 is similar to that of FIG. 1, except that a DC positive voltage is supplied from the DC supply unit 126 to the first electrode 112. By supplying a DC positive voltage to the first electrode 112, bulk electrons (bulk e⁻ of FIG. 4) become incident towards the first electrode 112, to thereby neutralize positive charges within an etched formation of the wafer W. Here, since the electron density rapidly reduces when the second high frequency power signal is turned OFF, the embodiment of FIG. 10 may not realize the same efficiency as that of the previous embodiments. As such, the embodiment of FIG. 10 may be particularly suited to the examples (a) and (c) of FIG. 6 in which the second high frequency power signal is ON during a portion of the Period 2(n). Otherwise, an operation of the embodiment of FIG. 10 (using a positive DC voltage) is the same as that described previously in connection with FIGS. 2-3 and 5-7, and accordingly, a detailed operational description of the embodiment of FIG. 10 is omitted here to avoid redundancy.

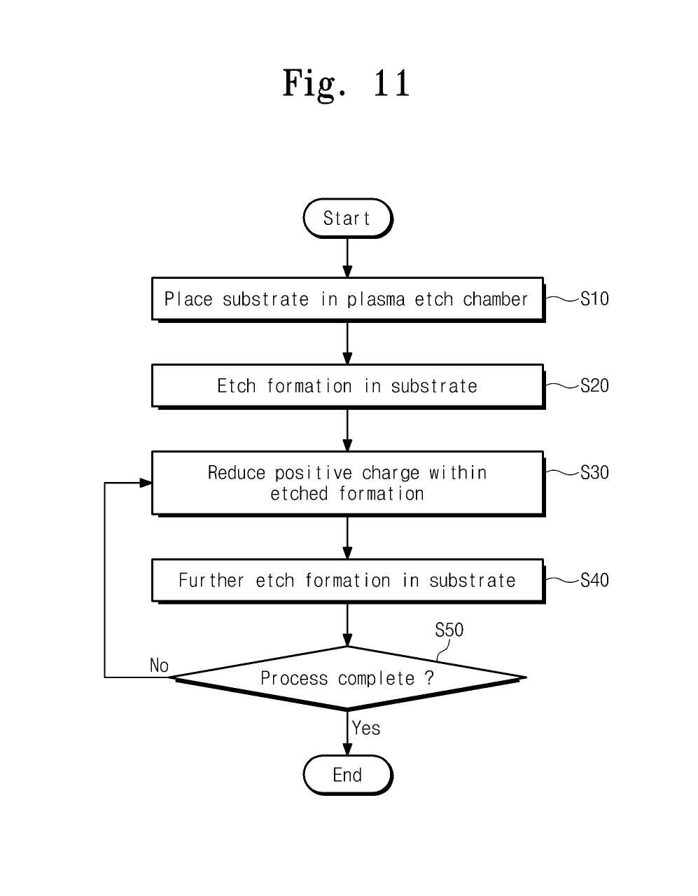

A plasma etching method according to one or more embodiments of the inventive concepts will now be described with reference to FIG. 11.

Initially, a substrate is placed in a plasma etch chamber (S10). Non-limiting examples of the plasma etch chamber includes those described above in connection with FIGS. 1 and 8-10. An etching process is then performed to etch a formation in the substrate placed in the etch chamber (S20). A positive charge within the etch formation is then reduced (S30), to thereby enhance an etching efficacy of a subsequent etch process. An etching process is performed again to further etch the formation in the substrate (S40). In the case where the plasma etching is to continue (NO at S50), the process again reduces a positive charge within the etch formation (S30), and then executes another etching process to further etch the formation (S40). The reduction of positive charge (S30) and etching of the formation (S40) are repeated until the formation is fully formed (YES at S50).

The above-disclosed subject matter is to be considered illustrative and not restrictive, and the appended claims are intended to cover all such modifications, enhancements, and other embodiments, which fall within the true spirit and scope of the inventive concept. Thus, to the maximum extent allowed by law, the scope of the inventive concept is to be determined by the broadest permissible interpretation of the following claims and their equivalents, and shall not be restricted or limited by the foregoing detailed description.

What is claimed is:

1. A method of etching a substrate, comprising:
positioning the substrate on a substrate support within a chamber;
etching a formation in the substrate in the presence of plasma within the chamber;
decreasing a positive charge within the formation; and
further etching the formation in the substrate in the presence of plasma after decreasing the positive charge within the formation.

2. The method of claim 1, wherein a bottom region of the formation has a net negative charge as a result of decreasing the positive charge within the formation.

3. The method of claim 1, wherein decreasing the positive charge within the formation includes introducing electrons into the formation.

4. The method of claim 1, wherein the substrate support includes a first electrode, and the chamber includes a second electrode spaced from the first electrode;
wherein the etching the formation in the substrate includes applying a pulsed first frequency power signal to the first electrode and a pulsed second frequency power signal to one of the first electrode and the second electrode, the first frequency power signal having a lower frequency than the second frequency power signal;
wherein the decreasing the positive charge within the formation includes changing the magnitude of a DC voltage applied to one of the first and second electrodes during a pulse-off period of at least one of the pulsed first and second frequency power signals.

5. The method of claim 4, wherein the changing the magnitude of the DC voltage includes increasing the magnitude of a negative voltage applied to the second electrode.

6. The method of claim 4, wherein the DC voltage is a pulsed DC voltage applied to the second electrode, wherein each pulse cycle of the pulsed DC voltage includes a low voltage pulse period and a high voltage pulse period, and wherein at least a portion of the low voltage pulse period is 0V or a first negative voltage (V1), and wherein a least a portion of the high voltage pulse period is a second negative voltage (V2), where |V2|>|V1|, and
wherein at least a portion of each high voltage pulse period of the pulsed DC voltage overlaps at least a portion of respective pulse-off periods of the pulsed first and second frequency power signals

7. The method of claim 6, wherein V1 is in a range of 0V to −500V, and wherein V2 is in a range of −200V to −2000V.

8. The method of claim 6, wherein each high voltage pulse period of the pulsed DC voltage includes multiple voltage pulses.

9. The method of claim 6, wherein each high voltage pulse period of the pulsed DC voltage includes a sloped voltage pulse.

10. The method of claim 4, wherein the changing the magnitude of the DC voltage includes increasing the magnitude of a positive voltage applied to the first electrode.

11. The method of claim 4, wherein the first and second frequency power signals are radio frequency (RF) signals.

12. The method of claim 4, wherein the frequency of the first frequency power signal is 15 MHz or less, and the frequency of the second frequency power signal is in the radio frequency (RF) range or higher.

13. The method of claim 4, wherein the first frequency power signal is pulse modulated in synchronization with the second frequency power signal.

14. The method of claim 6, wherein a pulse-on period of the second frequency power signal partially overlaps the high voltage pulse period of the pulsed DC voltage.

15. The method of claim 6, wherein the pulse-on period of the second frequency power signal includes a first pulse period which partially overlaps the pulse-on period of the first frequency power signal, and a second pulse period which partially overlaps the high voltage pulse period of the pulsed DC voltage.

16. The method of claim 1, wherein the substrate support includes a first electrode, wherein an induction coil is adjacent the chamber, and wherein the chamber includes a second electrode spaced from the first electrode;
wherein the etching the formation in the substrate includes applying a pulsed first frequency power signal to the first electrode and a pulsed second frequency power signal to the induction coil, the first frequency power signal having a lower frequency than the second frequency power signal;
wherein the decreasing the positive charge within the formation includes changing the magnitude of a DC voltage applied to one of the first and second electrodes during a pulse-off period of at least one of the first and second frequency power signals.

17. The method of claim 16, wherein changing the magnitude of the DC voltage includes increasing the magnitude of a negative voltage applied to the second electrode.

18. A method of etching a substrate, comprising:
applying pulsed first and second frequency power signals to an etch chamber to cyclically etch a formation in the substrate within the etch chamber, wherein a frequency of the first frequency power signal is less than a frequency of the second frequency power signal;
applying a pulsed DC voltage to an electrode within the chamber; and
synchronizing the pulsed first and second frequency power signals and the pulsed DC voltage to periodically reduce a positive charge within the formation during the cyclical etching of the formation.

19. The method of claim 18, wherein a pulse frequency of each of the pulsed first and second frequency power signals and the pulsed DC voltage is in a range of 100 Hz to 100 kHz.

20. The method of claim 19, wherein a pulse duty ratio of each of the pulsed first and second frequency power signals and the pulsed DC voltage is in a range of 10% to 99%.

21. The method of claim 18, wherein each pulse cycle of the pulsed DC voltage includes a low voltage pulse period and a high voltage pulse period, and
wherein at least a portion of the low voltage pulse period is 0V or a first negative voltage (V1), and wherein at least a portion of the high voltage pulse period is a second negative voltage (V2), where |V2|>|V1|, and
wherein at least a portion of each high voltage pulse period of the pulsed DC voltage at least partially overlaps respective pulse-off periods of the pulsed first and second frequency power signals

22. The method of claim 21, wherein each high voltage pulse period is at least one of a continuous voltage pulse, a sloped voltage pulse and a multi-pulse voltage pulse.

23. A method of etching a substrate, comprising:
positioning the substrate on a substrate support including a first electrode in a chamber;
etching a formation in the substrate by applying a pulsed first frequency power signal to the first electrode, and by applying a negative DC voltage and a pulsed second frequency power signal to a second electrode which is spaced from the first electrode, wherein the first frequency is less than the second frequency, and wherein a pulse-off period of the first frequency power signal at least partially overlaps a pulsed-off period of the second frequency power signal;
decreasing a positive charge within the chamber by increasing the magnitude of the negative DC voltage during at least a portion of an overlapping pulse-off period of the first and second frequency power signals; and
further etching the formation in the substrate by decreasing the magnitude of the negative DC voltage.

24. An etching apparatus, comprising:
a chamber;
a substrate support in the chamber and including a first electrode;
a second electrode in the chamber and spaced from the first electrode;
a high frequency supply unit configured to supply a pulsed first frequency power signal to the first electrode and a pulsed second frequency power signal to one of the first and second electrodes, wherein a frequency of the first frequency power signal is less than a frequency of the second frequency power signal;
a DC supply unit configured to supply a pulsed DC voltage to one of the first and second electrodes;
a control unit configured to synchronize the pulsed DC voltage and the pulsed first and second frequency power signals such that a magnitude of pulsed DC voltage is increased during at least a portion of each pulse-off period of the first and second frequency power signals.

25. The etching apparatus of claim 24, wherein the second frequency power signal is supplied to the first electrode, and wherein the high frequency supply unit comprises:
a first signal source configured to generate the first frequency power signal;
a second signal source configured to generate the second frequency power signal; and
a matching unit configured to match an impedance of the first and second signal sources with an impedance of the first electrode.

26. The etching apparatus of claim 25, wherein the matching unit is responsive to the control unit to pulse modulate the first and second frequency power signals generated by the first and second signal sources.

27. The etching apparatus of claim 24, wherein the second frequency power signal is supplied to the second electrode, and wherein the high frequency supply unit comprises:
a first signal source configured to generate the first frequency power signal;
a second signal source configured to generate the second frequency power signal;
a first matching unit configured to match an impedance of the first signal source with an impedance of the first electrode; and
a second matching unit configured to match an impedance of the second signal source with an impedance of the second electrode.

28. The etching apparatus of claim 26, wherein the first matching unit is responsive to the control unit to pulse modulate the first frequency power signal generated by the first signal source, and the second matching unit is responsive to the control unit to pulse modulate the second frequency power signal generated by the second signal source.

29. The etching apparatus of claim 24, wherein the pulsed DC voltage is applied to the second electrode.

30. The etching apparatus of claim 29, wherein the pulsed DC voltage is 0V or a first negative voltage (V1) during at least a portion of pulse-on periods of the pulsed first and second frequency power signals, and a second negative voltage (V2) during at least a portion of the pulse-off periods of the pulsed first and second frequency signals, where |V2|>|V1|.

31. The etching apparatus of claim 30, wherein the pulsed DC voltage is supplied to the first electrode.

32. The etching apparatus of claim 31, wherein the pulsed DC voltage is 0V or a first positive voltage (V1) during at least a portion of pulse-on periods of the pulsed first and second frequency power signals, and a second positive voltage (V2) during at least a portion of pulse-off periods of the pulsed first and second frequency signals, where |V2|>|V1|.

33. The etching apparatus of claim 24, wherein a pulse frequency of each of the pulsed first and second frequency power signals and the pulsed DC voltage is in a range of 100 Hz to 100 kHz.

34. The etching apparatus of claim 24, wherein a pulse duty ratio of each of the pulsed first and second frequency power signals and the pulsed DC voltage is in a range of 10% to 99%.

35. The etching apparatus of claim 24, wherein the first and second frequency power signals are radio frequency (RF) signals.

36. The etching apparatus of claim 24, wherein the frequency of the first frequency power signal is 15 MHz or less, and the frequency of the second frequency power signal is in the radio frequency (RF) range or higher.

37. An etching apparatus, comprising:
a chamber;
a substrate support in the chamber and including a first electrode;
an inductive coil adjacent the chamber;
a high frequency supply unit configured to supply a pulsed first frequency power signal to the first electrode and a pulsed second frequency power signal to the inductive coil, wherein a frequency of the first frequency power signal is less than a frequency of the second frequency power signal;
a DC supply unit configured to supply a pulsed DC voltage to one of the first and second electrodes;
a control unit configured to synchronize the pulsed DC voltage and the pulsed first and second frequency power signals such that a magnitude of pulsed DC voltage is increased during at least a portion of each pulse-off period of the first and second frequency power signals.

38. The etching apparatus of claim 37, wherein the pulsed DC voltage is applied to the second electrode.

39. The etching apparatus of claim 38, wherein the pulsed DC voltage is 0V or a first negative voltage (V1) during at least a portion of pulse-on periods of the pulsed first and second frequency power signals, and a second negative voltage (V2) during at least a portion of the pulse-off periods of the pulsed first and second frequency signals, where |V2|>|V1|.

40. The etching apparatus of claim 37, wherein the pulsed DC voltage is supplied to the first electrode.

41. The etching apparatus of claim 40, wherein the pulsed DC voltage is 0V or a first positive voltage (V1) during at least a portion of pulse-on periods of the pulsed first and second frequency power signals, and a second positive voltage (V2) during at least a portion of pulse-off periods of the pulsed first and second frequency signals, where |V2|>|V1|.
